(19) United States
(12) Patent Application Publication
(10) Pub. No.: US 2011/0036711 A1
(43) Pub. Date: Feb. 17, 2011

(54) SPUTTERING DEVICE

(75) Inventor: CHUNG-PEI WANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/764,935

(22) Filed: Apr. 21, 2010

(30) Foreign Application Priority Data
Aug. 14, 2009 (CN) 200910305618.8

(51) Int. Cl. C23C 14/34

(52) U.S. Cl. 204/298.28

(57) ABSTRACT

A sputtering device is provided. The sputtering device comprises a housing defining a chamber, and a carrier arranged within the housing. The carrier comprises a base, a plurality of supporting members, a plurality of spacing members, and a cap. The supporting members are spaced from each other and rotatably connected to the base. Each supporting member defines at least one cavity to receive at least one workpiece. The spacing members are fixed to the base, each of which is arranged between two adjacent supporting members. The cap is arranged above the plurality of supporting members and the plurality of spacing members to form a substantially enclosed space. The driving device is used to drive the carrier to rotate and to drive the plurality of supporting members to rotate with respect to the base.

### BACKGROUND

1. Technical Field

The present disclosure relates to sputtering devices and, more particularly, to a sputtering device capable of minimizing the mutual contamination of two different targets during the process of coating multiple layers of film onto workpieces.

2. Description of Related Art

Sputtering is a process whereby atoms are ejected from a solid target material due to bombardment of the target by energetic particles, which is commonly used for thin film deposition. In certain conditions, workpieces need to be deposited with multiple layer films by sputtering. Different targets are thus needed and are usually bombarded in the same chamber of a sputtering device. However, the different targets bombarded in the same chamber may tend to contaminate each other.

Therefore, what is needed is a sputtering device to overcome the aforementioned problem.

### BRIEF DESCRIPTION OF THE DRAWINGS

The components in the drawings are not necessarily drawn to scale, the emphasis instead being placed upon clearly illustrating the principles of the sputtering device. Moreover, in the drawings, like reference numerals designate corresponding parts throughout the several views.

FIG. 1 is an isometric view of a sputtering device in accordance with an exemplary embodiment.

FIG. 2 is an isometric view of a carrier of the sputtering device of FIG. 1.

FIG. 3 is an isometric, exploded view of the carrier of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

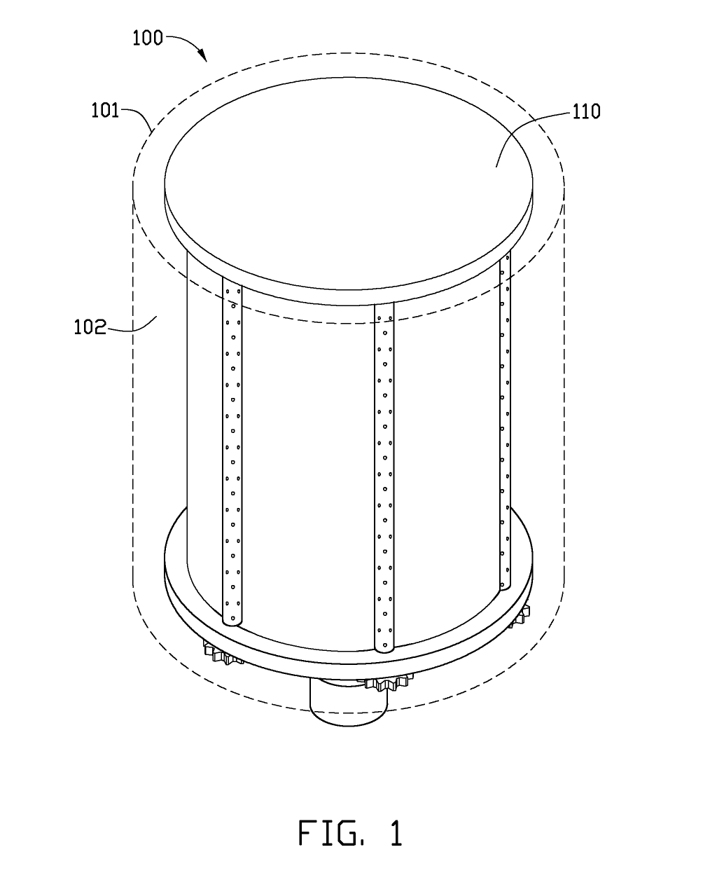

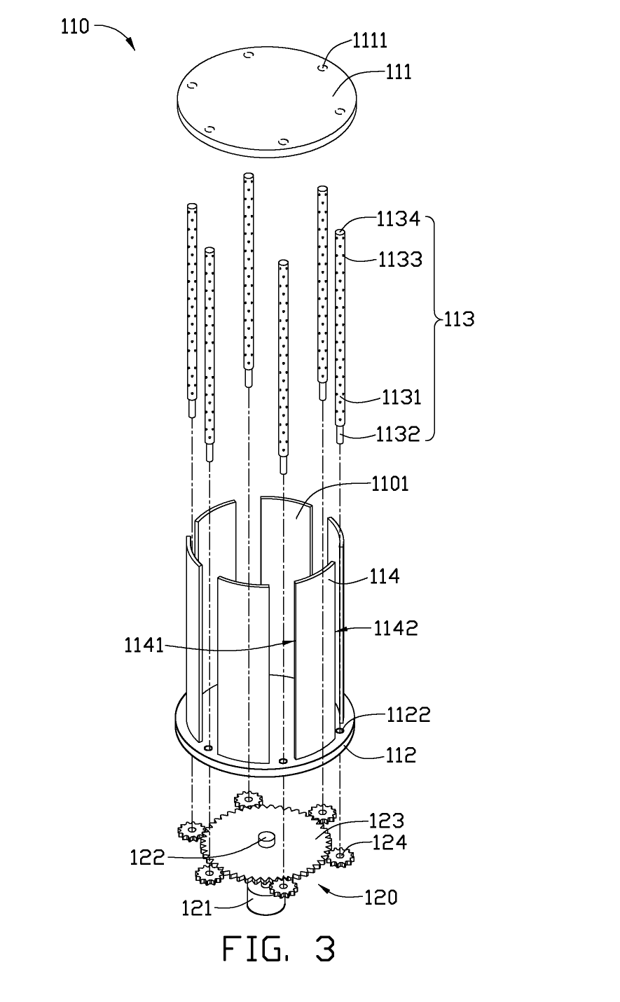

Referring to FIGS. 1-3, a sputtering device 100 includes a housing 101 that defines a chamber 102 to accommodate a first target (not shown). The sputtering device 100 also includes a carrier 110 to accommodate workpieces (not shown) to be coated.

The carrier 110 is arranged within the chamber 102 and includes a cap 111, a base 112, a plurality of supporting members 113, and a plurality of spacing members 114, which forms a substantially closed space 1101. A second target (not shown) is arranged within the closed space 1101. The first and second targets are thus separated from each other. The mutual contamination of the first and second targets are thus minimized.

The cap 111 and base 112 are round plates. The base 112 defines a plurality of through holes 1122. The through holes 1122 are formed along a circle, such that the supporting members 113 each including a rotating end 1132 fitting into the through hole 1122 are also arranged along a circle. The arrangement of the through holes 1122 is not limited and may be modified according to need. The cap 111 also defines a plurality of blind holes 1111 corresponding to the through holes 1122, such that an end 1134 of the supporting member 113 that is opposite to the rotating end 1132 can be received in the blind holes 1111.

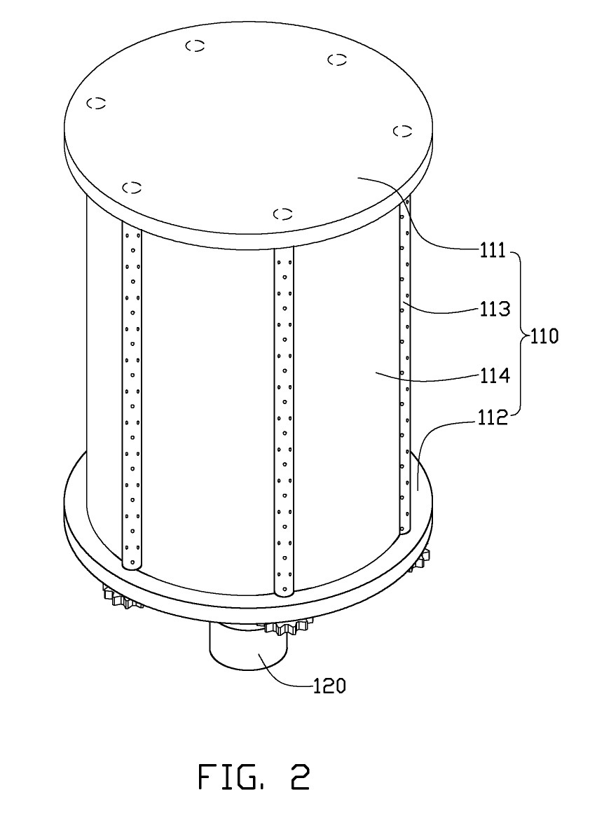

The supporting member 113 is generally cylindrical and is rotatably connected to the base 112 by the rotating end 1132 fitting into and extending through the through holes 1122. Each of the supporting member 113 includes a lateral surface 1131 defining at least one cavity 1133. One or more workpieces are arranged within the cavity 1133. It is noteworthy that the size, number, shape, and distribution of cavities 1133 in FIGS. 1 and 2 are shown for illustration purposes only and are not meant to be a limitation of the present disclosure. The size, number, shape, and distribution of cavities 1133 may be modified according to need.

The supporting member 113 rotates to allow the workpiece to be arranged within the cavity 1133 and can be orientated to face the first or second target. Ions or neutral particles from the first or the second target can thus be ejected onto the workpiece. The workpiece can thus be coated with multiple layers of film.

The spacing members 114 are rectangular panels deformed slightly and each is arranged between two adjacent supporting members 113. The cap 111 and the base 112 can be attached to the two ends of the spacing members 114 by any conventional connection technique. To form an effective closed space 1101, two sides 1141 and 1142 of the spacing members 114 may be deformed slightly and elastically, such that the two sides 1141 and 1142 engage the supporting members tightly, but do not prevent the rotation of the supporting members 113.

The sputtering device 100 also includes a driving device 120 to drive the carrier 110 and its supporting members 113. The driving device 120 includes a motor 121 having a motor shaft 122, a drive gear 123, and a plurality of slave gears 124. The motor shaft 121 is fixed to the base 112 to drive the carrier 110 to rotate. The drive gear 123 is connected to the motor shaft 122. Each slave gear 124 is connected to the rotating end 1132. The drive gear 123 engages the slave gears 124 to form a transmission mechanism that transmits rotation from the motor shaft 122 to the supporting members 113.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A sputtering device comprising:
a housing defining a chamber;
a carrier arranged within the chamber, comprising:
a base;
a plurality of supporting members spaced from each other and rotatably connected to the base, each of the plurality of supporting members defining at least one cavity to receive at least one workpiece;
a plurality of spacing members fixed to the base, each of the plurality of spacing members arranged between two adjacent supporting members; and
a cap arranged above the plurality of supporting members and the plurality of spacing members to form a substantially enclosed space; and
a driving device to drive the carrier to rotate and to drive the plurality of supporting members to rotate with respect to the base.

2. The sputtering device according to claim 1, wherein the plurality of supporting members are arranged along a circle.

3. The sputtering device according to claim 1, wherein the base is a plate defining a plurality of through holes, each of the plurality of supporting members includes an end fit into one of the plurality of through holes to allow rotation with respect to the base.

4. The sputtering device according to claim 1, wherein the at least one cavity is formed in a lateral surface of each supporting member.

5. The sputtering device according to claim 1, wherein the driving device comprises a motor having a motor shaft connected to the base, and a transmission mechanism to transmit rotation from the motor shaft to the plurality of supporting members.

6. The sputtering device according to claim 5, wherein the transmission mechanism includes a drive gear connected to the motor shaft and a plurality of sleeve gears, each of which is connected to one of the end of the plurality of supporting members.

7. A carrier for use in a sputtering device comprising a driving device to drive the carrier to rotate and defining a chamber, the carrier comprising:
a base;
a plurality of supporting members spaced from each other and rotatably connected to the base, each of the plurality of supporting members defining at least one cavity to receive at least one workpiece, wherein the plurality of supporting members are driven by the driving device to rotate;
a plurality of spacing members fixed to the base, each of the plurality of spacing members arranged between two adjacent supporting members; and
a cap arranged above the plurality of supporting members and the plurality of spacing members to form a substantially enclosed space.

8. The carrier according to claim 7, wherein wherein the plurality of supporting members are arranged along a circle.

9. The carrier according to claim 7, wherein the base is a plate defining a plurality of through holes, each of the plurality of supporting members includes an end fit into one of the plurality of through holes to allow rotation with respect to the base.

10. The carrier according to claim 7, wherein the at least one cavity is formed in a lateral surface of the supporting member.

11. The carrier according to claim 7, wherein driving device comprises a motor having a motor shaft connected to the base, and a transmission mechanism to transmit rotation from the motor shaft to the plurality of supporting members.

12. The carrier according to claim 11, wherein the transmission mechanism includes a drive gear connected to the motor shaft and a plurality of sleeve gears, each of which is connected to one of the end of the plurality of supporting members.
